(19) United States
(12) Patent Application Publication
(10) Pub. No.: US 2026/0363080 A1
(43) Pub. Date: Nov. 12, 2026

(54) SEMICONDUCTOR DEVICE, AND METHOD OF MANUFACTURING THE SAME

(71) Applicant: Mitsubishi Electric Corporation, Tokyo (JP)

(72) Inventors: Yuki YOSHIOKA, Tokyo (JP); Yuki YANO, Tokyo (JP)

(73) Assignee: Mitsubishi Electric Corporation, Tokyo (JP)

(21) Appl. No.: 19/142,392

(22) PCT Filed: Mar. 9, 2023
(86) PCT No.: PCT/JP2023/009053

§ 371 Date: Jun. 23, 2025

(51) Int. Cl. H10W 40/77; H10W 40/20; H10W 40/22; H10W 72/00; H10W 74/10; H10W 74/47; H10W 90/00; H10W 90/10

(52) U.S. Cl. CPC H10W 40/778; H10W 40/226; H10W 40/237; H10W 72/07533; H10W 72/865; H10W 72/884; H10W 74/114; H10W 90/10; H10W 90/734; H10W 90/736; H10W 90/756; H10W 74/47

(57) ABSTRACT

A semiconductor device of the present disclosure includes a conductive heat dissipation member. The heat dissipation member includes a plurality of column portions and a plate portion provided between the plurality of column portions. The heat dissipation member is provided away from the plurality of semiconductor elements so that a sealing resin layer between the heat dissipation member and the plurality of semiconductor elements does not cause dielectric breakdown during energization operation of the plurality of semiconductor elements. Furthermore, the heat dissipation member is electrically insulated from the plurality of semiconductor elements.

### TECHNICAL FIELD

The present disclosure relates to a semiconductor device and a method of manufacturing the same, and more particularly, to a semiconductor device having a structure for dissipating heat generated in a semiconductor element via a base plate.

### BACKGROUND ART

As a semiconductor device having a structure for dissipating heat generated in a semiconductor element, for example, there is a semiconductor device disclosed in Patent Document 1.

The conventional semiconductor device disclosed in Patent Document 1 is provided with a heat dissipation mechanism that alleviates thermal stress acting on a joint portion between the semiconductor element and connection wiring due to a difference in thermal expansion coefficient between the component parts. Specifically, in the conventional semiconductor device, a thermal stress buffer member is interposed between the semiconductor element and the connection wiring, and the thermal stress buffer member is bonded to each of the semiconductor element and the connection wiring to implement the heat dissipation mechanism. The thermal stress buffer member used for the heat dissipation mechanism is made of a composite material in which a metal having a melting point lower than that of the above-described base material is infiltrated and dispersed in a carbon base material or a sintered body of a metal base material.

### PRIOR ART DOCUMENT

### Patent Document

Patent Document 1: Japanese Patent Application Laid-Open No. 2008-42041

### SUMMARY

### Problem to be Solved by the Invention

A conventional semiconductor device having a heat dissipation mechanism generally adopts, as a heat dissipation mechanism, a single-sided cooling system in which a semiconductor element is cooled from an insulating substrate side by bonding the semiconductor element via an insulating substrate. In the conventional semiconductor device, since an upper surface of the semiconductor element is sealed with a sealing resin layer, heat generated by the semiconductor element during energization operation is accumulated in the sealing resin layer. Since the sealing resin layer is provided on a side opposite to the insulating substrate with respect to the semiconductor element, it is difficult to dissipate the heat accumulated in the sealing resin layer in the conventional heat dissipation mechanism adopting the single-sided cooling system described above.

When component parts (hereinafter sometimes simply referred to as “components”) generally used in a semiconductor device are a semiconductor element, a connection wiring, an insulating substrate, a base plate, and a sealing resin layer, the thermal expansion coefficient of a component is, for example, a value in a range of {2×10⁻⁶/K~22×10⁻⁶/K}. Therefore, the maximum difference in linear expansion coefficient between the components of the conventional semiconductor device can be as high as 20×10⁻⁶/K.

In general, the difference in thermal expansion coefficient between components is preferably 9×10⁻⁶/K or less. Therefore, the maximum difference in thermal expansion coefficient in the conventional semiconductor device is not negligible. In particular, the connection wiring and the base plate tend to be components that increase the difference in thermal expansion coefficient.

Under such circumstances, the sealing resin layer is in contact with all the components, and is particularly greatly affected by the difference in thermal expansion coefficient. Components included in the semiconductor device include the above-described semiconductor element, connection wiring, insulating substrate, base plate, and the like.

Assume that a junction temperature Tj during energization operation of the semiconductor element rises to 125 °C, for example. Since the conventional semiconductor device has a cooling mechanism of a single-sided cooling system, the temperature of each component is kept close to the design value temperature of the cooling mechanism. However, the temperature of the sealing resin layer provided on the upper surface of the semiconductor element rises to 125 °C, and heat propagates to the entire sealing resin layer. As a result, the sealing resin layer peels off from each component due to a difference in thermal expansion coefficient between the sealing resin layer and each component. Therefore, there is a problem that the reliability of the semiconductor device is lowered.

The conventional semiconductor device disclosed in Patent Document 1 has a structure in which a thermal stress buffer member is interposed between the semiconductor element and the connection wiring. Therefore, by cooling the heat generated during energization operation of the semiconductor element via the thermal stress buffer member, the thermal stress generated at the interface between the semiconductor element and the sealing resin layer is alleviated, the occurrence of peeling between the semiconductor element and the sealing resin layer is prevented, and the reliability of the device is improved.

However, since the thermal stress buffer member is electrically connected to the semiconductor element constituting the main current circuit and functions as a part of the wiring of the semiconductor element, there is a problem that an electrical loss occurs during energization operation of the semiconductor element. Note that, for example, an increase in inductance is considered as the electrical loss.

An object of the present disclosure is to solve the above problems and provide a structure of a semiconductor device in which reliability of the device is improved without causing electrical loss during operation of a semiconductor element.

### Means to Solve the Problem

A semiconductor device according to the present disclosure includes: a base plate having a first main surface and a second main surface; an insulating circuit board provided on a first main surface side of the base plate and having a circuit pattern; at least one semiconductor element provided on a first main surface side of the insulating circuit board; a heat dissipation member having conductivity and including a plurality of column portions and a plate portion provided between the plurality of column portions, the plate portion being located on a first main surface side of the insulating circuit board and the at least one semiconductor element, the plurality of column portions being provided in a state of standing on the first main surface of the base plate; and a resin layer provided on a first main surface of the base plate so as to cover the insulating circuit board, the at least one semiconductor element, and the heat dissipation member. The heat dissipation member is provided away from the at least one semiconductor element so that the resin layer between the heat dissipation member and the at least one semiconductor element does not cause dielectric breakdown during operation of the at least one semiconductor element, and the heat dissipation member is electrically insulated from the at least one semiconductor element.

### Effects of the Invention

Since the heat dissipation member in the semiconductor device of the present disclosure is electrically insulated from the at least one semiconductor element, the presence of the heat dissipation member does not cause electrical loss during operation of the at least one semiconductor element.

In addition, since the heat dissipation member is provided away from the at least one semiconductor element so that the resin layer does not cause dielectric breakdown during operation of the at least one semiconductor element, the heat dissipation member does not cause dielectric breakdown in the resin layer during operation of the at least one semiconductor element.

Furthermore, since the heat dissipation member has conductivity and is provided such that the column portion stands on the first main surface of the base plate, it is possible to exhibit a heat dissipation function of dissipating heat accumulated in the resin layer during operation of at least one semiconductor element via a heat dissipation path including the heat dissipation member and the base plate.

Therefore, in the semiconductor device of the present disclosure, the influence of the difference in thermal expansion coefficient between the resin layer and other component parts is alleviated, and peeling at the interface between the resin layer and each of the at least one semiconductor element, the insulating circuit board, and the base plate can be reliably avoided.

As a result, the semiconductor device of the present disclosure can enhance the reliability of the device without causing electrical loss during operation of at least one semiconductor element.

Objects, features, aspects, and advantages of the present disclosure will become more apparent from the following detailed description and the accompanying drawings.

### BRIEF DESCRIPTION OF DRAWINGS

FIG. 1 is a plan view illustrating a top surface structure of a semiconductor device of Embodiment 1.

FIG. 2 is a cross-sectional view (part 1) illustrating a cross-sectional structure of the semiconductor device of Embodiment 1 illustrated in FIG. 1.

FIG. 3 is a cross-sectional view (part 2) illustrating a cross-sectional structure of the semiconductor device of Embodiment 1 illustrated in FIG. 1.

FIG. 4 is a plan view illustrating a top surface structure of a semiconductor device of Embodiment 2.

FIG. 5 is a cross-sectional view illustrating a cross-sectional structure of a semiconductor device of Embodiment 3.

FIG. 6 is a plan view illustrating a top surface structure of a semiconductor device of Embodiment 4.

FIG. 7 is a cross-sectional view (part 1) illustrating a cross-sectional structure of the semiconductor device of Embodiment 4 illustrated in FIG. 6.

FIG. 8 is a cross-sectional view (part 2) illustrating a cross-sectional structure of the semiconductor device of Embodiment 4 illustrated in FIG. 6.

FIG. 9 is a cross-sectional view illustrating a cross-sectional structure of a semiconductor device of Embodiment 5.

FIG. 10 is a cross-sectional view illustrating a cross-sectional structure of a semiconductor device of Embodiment 6.

### DESCRIPTION OF EMBODIMENTS

### Embodiment 1

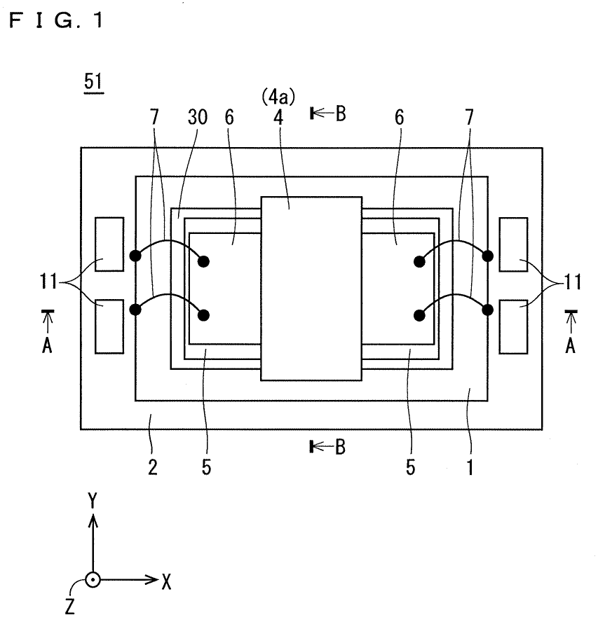

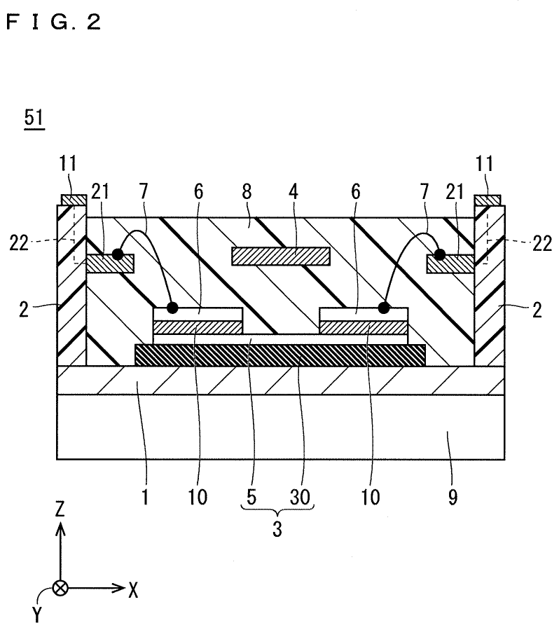

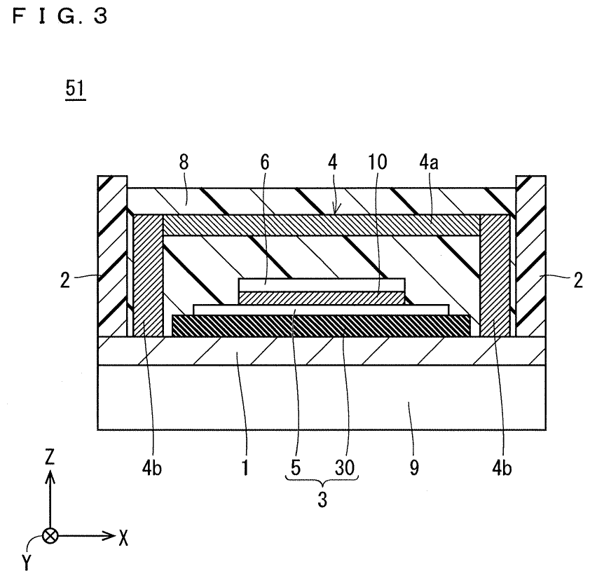

FIG. 1 is a plan view illustrating a top surface structure of a semiconductor device 51 of Embodiment 1 of the present disclosure. FIG. 2 is a cross-sectional view illustrating an A-A cross-sectional structure of the semiconductor device 51 of Embodiment 1 illustrated in FIG. 1. FIG. 3 is a cross-sectional view illustrating a B-B cross-sectional structure of the semiconductor device 51 of Embodiment 1 illustrated in FIG. 1. An XYZ orthogonal coordinate system is illustrated in each of FIGS. 1 to 3. Note that in FIG. 1, a sealing resin layer 8 is omitted in order to clearly show the internal structure of the semiconductor device 51.

Hereinafter, each component part of the semiconductor device 51 illustrated in FIGS. 2 and 3 which are cross-sectional views will be described with the upper end of the drawing being referred to as a “first main surface” and the lower end of the drawing being referred to as a “second main surface”. That is, in each component of the semiconductor device 51, the surface on the +Z direction side is the “first main surface”, and the surface on the-Z direction side is the “second main surface”.

For example, an upper surface of a metal base plate 1 which is a base plate serves as the first main surface, and a lower surface thereof serves as the second main surface. Furthermore, in describing the structure of the semiconductor device 51, the +Z direction may be referred to as a first main surface side and the −Z direction may be referred to as a second main surface side with respect to each component.

As illustrated in FIGS. 1 to 3, a resin case 2 is provided on the first main surface of the metal base plate 1 which is a base plate. The metal base plate 1 is made of a material having excellent heat conduction, such as an aluminum alloy or copper.

The resin case 2 has a rectangular frame structure formed of side walls having a four-side structure in plan view on the XY plane, and is provided on a peripheral region of the first main surface of the metal base plate 1. A plurality of external electrodes 11 are provided on an upper surface of the side wall of the resin case 2. In FIG. 2, two external electrodes 11 are illustrated as the plurality of external electrodes 11. Note that the resin case 2 is made of a resin having high heat resistance, such as poly phenylene sulfide (PPS) or polybutylen terefthalate (PBT).

The combination of the metal base plate 1 and the resin case 2 constitutes an upper release type housing having an accommodation region therein with the metal base plate 1 as a bottom surface and the resin case 2 as a side surface.

A plurality of intermediate connection members 21 are provided corresponding to the plurality of external electrodes 11 from an inner surface of the side wall to the inside of the resin case 2. FIG. 2 illustrates two intermediate connection members 21 as the plurality of intermediate connection members 21. Between the plurality of external electrodes 11 and the plurality of intermediate connection members 21, the corresponding external electrode 11 and intermediate connection member 21 are electrically connected via an embedded connection line 22. The embedded connection line 22 is embedded in the side wall of the resin case 2. As described above, the plurality of external electrodes 11, the plurality of intermediate connection members 21, and the plurality of embedded connection lines 22 correspond one-to-one.

An insulating circuit board 3 is provided on the first main surface of the metal base plate 1. The insulating circuit board 3 is provided so as to be accommodated in an accommodation region formed by a combination of the metal base plate 1 and the resin case 2.

The insulating circuit board 3 is a board having a combination structure of an insulating layer 30 and circuit patterns 5 provided on both surfaces of the insulating layer 30. The insulating layer 30 is made of, for example, a ceramic or resin having excellent thermal conductivity, such as aluminum nitride or silicon nitride.

The circuit pattern 5 is provided on both surfaces of the insulating layer 30. The circuit pattern 5 is made of an aluminum alloy, copper, or the like. Note that in the cross-sectional views illustrated in FIGS. 2 and 3 and the following drawings, illustration of the circuit pattern 5 provided on the second main surface of the insulating layer 30 is omitted.

Furthermore, a plurality of semiconductor elements 6 are provided on the first main surface of the circuit pattern 5 via a conductive bonding material 10. FIGS. 1 to 3 illustrate two semiconductor elements 6 as the plurality of semiconductor elements. The conductive bonding material 10 is made of solder, soft wax, or the like. Therefore, the circuit pattern 5 of the insulating circuit board 3 and the plurality of semiconductor elements 6 are bonded via the conductive bonding material 10.

Each of the plurality of semiconductor elements 6 is electrically connected to the intermediate connection member 21 via an electrical connection member 7. Therefore, signals flowing during energization operation of the plurality of semiconductor elements 6 can be obtained from the plurality of external electrodes 11.

Note that as each of the plurality of semiconductor elements 6, an insulated gate bipolar transistor (IGBT), a diode, or a reverse conducting IGBT made of a silicon (Si) material is often used. Furthermore, as each of the plurality of semiconductor elements 6, a metal-oxide-semiconductor field effect transistor (MOSFET), a Schottky diode, or the like made of a material having a larger band gap than that of Si such as gallium nitride (GaN) may be used.

In addition, the number of semiconductor elements 6 mounted on the first main surface side of the insulating circuit board 3 is not limited, and a required number of semiconductor elements 6 are mounted according to the application. That is, the semiconductor device 51 of Embodiment 1 only needs to have at least one semiconductor element 6.

Hereinafter, a structure including the insulating circuit board 3, the plurality of semiconductor elements 6, and the plurality of conductive bonding materials 10 may be referred to as an “intermediate structure”.

In the semiconductor device 51 of Embodiment 1, the electrical connection member 7 is illustrated schematically. That is, the electrical connection member 7 includes a linear connection member such as a wire to be bonded and fixed by ultrasonic wire bonding processing, and a plate-like connection member having a main portion formed in a plate shape. In FIGS. 1 to 3, the electrical connection member 7 is illustrated as a linear connection member.

In such a configuration, a main current circuit is formed including the plurality of semiconductor elements 6, the electrical connection member 7, and the circuit pattern 5 portion of the insulating circuit board 3. The main current circuit is a circuit through which a main current flows during energization operation of the plurality of semiconductor elements 6.

The semiconductor device 51 of Embodiment 1 further includes a heat dissipation member 4. The heat dissipation member 4 has conductivity, includes a plurality of column portions 4b and one plate portion 4a provided between the plurality of column portions 4b, and has a flat gate shape in the XZ cross section as illustrated in FIG. 3. In FIG. 3, two column portions 4b are illustrated as the plurality of column portions 4b. As illustrated in FIG. 1, the plate portion 4a of the heat dissipation member 4 has a rectangular shape in plan view on the XY plane.

In addition, as illustrated in FIG. 3, the second main surface of the plate portion 4a and the first main surface of each component constituting the intermediate structure are arranged to face each other. Specifically, as illustrated in FIGS. 2 and 3, the plate portion 4a of the heat dissipation member 4 is disposed at a position spaced apart from the first main surface of each of the insulating circuit board 3 and the plurality of semiconductor elements 6 in the +Z direction. That is, the plate portion 4a of the heat dissipation member 4 is located on the first main surface side of the insulating circuit board 3 and the plurality of semiconductor elements 6.

As illustrated in FIG. 3, the plurality of column portions 4b are provided to stand on the first main surface of the metal base plate 1 without being in contact with the intermediate structure. That is, some or all lower end portions of the plurality of column portions 4b are in contact with each other on the first main surface of metal base plate 1. As described above, the heat dissipation member 4 is provided above the first main surface of the metal base plate 1 so as to straddle the intermediate structure.

Then, the sealing resin layer 8 which is a resin layer is provided so as to close the accommodation region of the resin case 2. That is, the accommodation region is sealed by filling with the sealing resin layer 8. As described above, the sealing resin layer 8 which is a resin layer is provided above the first main surface of the metal base plate 1 so as to cover the insulating circuit board 3, the circuit pattern 5, the plurality of semiconductor elements 6, the plurality of electrical connection members 7, and the heat dissipation member 4.

The sealing resin layer 8 is often made of silicone gel or epoxy resin, but is not limited thereto. The sealing resin layer 8 can be made of any material as long as the material has desired physical properties such as elastic modulus, heat resistance, adhesiveness, and linear expansion coefficient.

Therefore, the sealing resin layer 8 exists between the second main surface of the plate portion 4a of the heat dissipation member 4 and the intermediate structure. That is, the sealing resin layer 8 exists between the second main surface of the plate portion 4a and the first main surface of each of the plurality of semiconductor elements 6.

Furthermore, a cooling mechanism 9 is attached to the second main surface side of the metal base plate 1 which is a base plate. The cooling mechanism 9 adopts a water cooling system or an air cooling system, and executes a cooling operation for cooling the metal base plate 1. Therefore, the heat dissipation member 4 is cooled by the cooling operation of the cooling mechanism 9 via the metal base plate 1.

The heat dissipation member 4 is provided away from the plurality of semiconductor elements 6 so that the sealing resin layer 8 between the heat dissipation member 4 and the plurality of semiconductor elements 6 does not cause dielectric breakdown during energization operation of the plurality of semiconductor elements 6. In addition, the heat dissipation member 4 is electrically insulated from the plurality of semiconductor elements 6, and the potential of the heat dissipation member 4 is set to 0 V. The potential of the heat dissipation member 4 is set, for example, by setting 0 V as a reference potential to the metal base plate 1.

Hereinafter, the arrangement of the heat dissipation member 4 will be described in detail. For example, when the sealing resin layer 8 is made of a sealing resin having a dielectric breakdown voltage of 20 kV/mm and the operating voltage of the plurality of semiconductor elements 6 is 600 V, the heat dissipation member 4 is provided at a position separated by an insulation distance exceeding 30 μm between the plurality of semiconductor elements 6 and the heat dissipation member 4 during energization operation of the plurality of semiconductor elements 6. “30 μm” is a value obtained by dividing the operating voltage 600 V by the dielectric breakdown voltage 20 kV/mm. That is, the “insulation distance” can be calculated from two factors (dielectric breakdown voltage of sealing resin layer 8 and voltage during energization operation of semiconductor element 6).

Specifically, the distance between the second main surface of the plate portion 4a of the heat dissipation member 4 and the first main surface of each of the plurality of semiconductor elements 6 facing each other in the Z direction is set to satisfy the insulation distance. In addition, the shortest distance between each of the plurality of column portions 4b and the side surface of each of the plurality of semiconductor elements 6 is set to satisfy the insulation distance.

Note that preferably, the shortest distance between each of the plurality of column portions 4b and the side surface of each of the plurality of circuit patterns 5 is set to satisfy the insulation distance, and the shortest distance between each of the plurality of electrical connection members 7 and the heat dissipation member 4 is set to satisfy the insulation distance.

In addition, the plate portion 4a and the plurality of column portions 4b are disposed so as not to be in contact with any of the plurality of semiconductor elements 6, and the sealing resin layer 8 is provided between the heat dissipation member 4 and the plurality of semiconductor elements 6, whereby the heat dissipation member 4 is electrically insulated from the plurality of semiconductor elements 6.

As described above, since the heat dissipation member 4 in the semiconductor device 51 of Embodiment 1 is electrically insulated from the plurality of semiconductor elements 6, the presence of the heat dissipation member 4 does not cause electrical loss during operation of the plurality of semiconductor elements 6.

In addition, since the heat dissipation member 4 is provided away from the plurality of semiconductor elements by an insulation distance so that the sealing resin layer 8, which is a resin layer, does not cause dielectric breakdown during energization operation of the plurality of semiconductor elements 6, dielectric breakdown does not occur in the sealing resin layer 8 during energization operation of the plurality of semiconductor elements.

On the other hand, the heat dissipation member 4 is cooled via the metal base plate 1 by the cooling operation of the cooling mechanism 9. Therefore, the heat dissipation member 4 can exhibit a heat dissipation function of dissipating heat accumulated in the sealing resin layer 8 during energization operation of the plurality of semiconductor elements 6 via a heat dissipation path including the heat dissipation member 4 and the metal base plate 1.

That is, since the second main surface of the plate portion 4a of the heat dissipation member 4 is in contact with the sealing resin layer 8, heat accumulated in the sealing resin layer 8 can be effectively dissipated by the above-described heat dissipation function of the heat dissipation member 4.

As described above, in the semiconductor device 51 of Embodiment 1, the influence of the difference in thermal expansion coefficient between the sealing resin layer 8 and each component can be alleviated by the heat dissipation function of the heat dissipation member 4, so that peeling at the interface between each of the plurality of semiconductor elements 6, the insulating circuit board 3, and the metal base plate 1 and the sealing resin layer 8 can be reliably avoided.

As a result, the semiconductor device 51 of Embodiment 1 can enhance the reliability of the device without causing electrical loss during energization operation of the plurality of semiconductor elements 6.

Moreover, in the semiconductor device 51 of Embodiment 1, since there is no restriction on the arrangement of the plurality of electrical connection members 7, the degree of freedom in the arrangement of the plurality of electrical connection members 7 is relatively high.

In addition, in the semiconductor device 51 of Embodiment 1, a first cooling operation of cooling the first main surface side of the sealing resin layer 8 through the heat dissipation path of the heat dissipation member 4, the metal base plate 1, and the cooling mechanism 9, and a second cooling operation of cooling the second main surface side of the sealing resin layer 8 through the heat dissipation path of the insulating circuit board 3, the metal base plate 1, and the cooling mechanism 9 are executed together, so that a cooling operation of a double-sided cooling system can be performed on the sealing resin layer 8.

As described above, the semiconductor device 51 of Embodiment 1 executes the cooling operation of the double-sided cooling system including the first and second cooling operations described above, whereby heat accumulated in the sealing resin layer 8 can be effectively dissipated to alleviate the influence of the difference in thermal expansion coefficient between the sealing resin layer 8 and each component.

Furthermore, the semiconductor device 51 of Embodiment 1 can simplify the device configuration by executing the cooling operation of the double-sided cooling system described above by one cooling mechanism 9.

Note that although the structure including the plurality of semiconductor elements 6 has been described as the semiconductor device 51 of Embodiment 1, a structure including one semiconductor element 6 can also exhibit a similar effect. That is, the semiconductor device 51 of Embodiment 1 can be applied to a structure having at least one semiconductor element 6.

### Embodiment 2

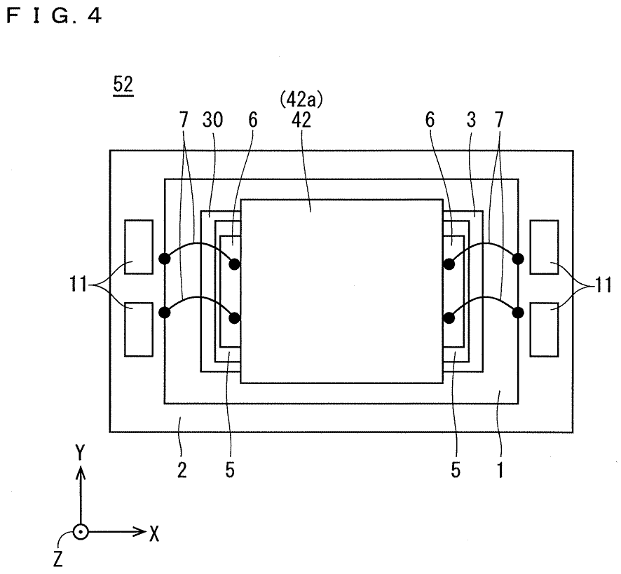

FIG. 4 is a plan view illustrating a top surface structure of semiconductor device 52 of Embodiment 2 of the present disclosure. An XYZ orthogonal coordinate system is illustrated in FIG. 4. Note that in FIG. 4, a sealing resin layer 8 is omitted in order to clearly show the internal structure of the semiconductor device 52. That is, FIG. 4 illustrates a state before resin sealing is performed by the sealing resin layer 8.

Hereinafter, components similar to those of the semiconductor device 51 illustrated in FIGS. 1 to 3 will be denoted by the same reference numerals, description thereof will be omitted as appropriate, and feature portions of the semiconductor device 52 of Embodiment 2 will be mainly described.

The semiconductor device 52 of Embodiment 2 has a structure in which the heat dissipation member 4 is replaced with a heat dissipation member 42.

The heat dissipation member 42 has conductivity and includes a plurality of column portions 42b (not illustrated) and a plate portion 42a provided between the plurality of column portions 42b. The plate portion 42a of the heat dissipation member 42 has a rectangular shape in plan view as illustrated in FIG. 4, and is disposed so as to overlap most of a plurality of semiconductor elements 6 in plan view. Specifically, except for the bonding region with a plurality of electrical connection members 7 on the first main surfaces of the plurality of semiconductor elements 6, the plate portion 42a of the heat dissipation member 42 overlaps the first main surfaces of the plurality of semiconductor elements 6 in plan view.

Similarly to the heat dissipation member 4 of Embodiment 1, the heat dissipation member 42 is disposed such that the second main surface of the plate portion 42a and the first main surface of an intermediate structure face each other. Therefore, the plate portion 42a of the heat dissipation member 42 is disposed at a position spaced apart from the first main surface of each of the insulating circuit board 3 and the plurality of semiconductor elements 6 in the +Z direction. That is, the plate portion 42a of the heat dissipation member 42 is located on the first main surface side of an insulating circuit board 3 and the plurality of semiconductor elements 6.

Similarly to the plurality of column portions 4b of Embodiment 1, the plurality of column portions 42b are provided so as to stand on the first main surface of the metal base plate 1. That is, similarly to the heat dissipation member 4 of Embodiment 1, the heat dissipation member 42 is provided on the first main surface of the metal base plate 1 so as to straddle the intermediate structure.

Then, similarly to the heat dissipation member 4 of Embodiment 1, the heat dissipation member 42 is provided away from the plurality of semiconductor elements 6 so that the sealing resin layer 8 between the heat dissipation member 42 and the plurality of semiconductor elements 6 does not cause dielectric breakdown during energization operation of the plurality of semiconductor elements 6. Furthermore, similarly to the heat dissipation member 4 of Embodiment 1, the heat dissipation member 42 is electrically insulated from the plurality of semiconductor elements 6.

In such a configuration, heat during energization operation of the plurality of semiconductor elements 6 is propagated to the entire semiconductor device 52 via the sealing resin layer 8.

In the semiconductor device 52 of Embodiment 2, most of the first main surface of each of the plurality of semiconductor elements 6 faces the second main surface of plate portion 42a. Therefore, by a first cooling operation of cooling through a heat dissipation path including the heat dissipation member 42, a metal base plate 1, and a cooling mechanism 9, heat generated by the plurality of semiconductor elements 6 and propagated to the sealing resin layer 8 is dissipated, and the temperature rise in the region of the sealing resin layer 8 close to the plurality of semiconductor elements 6 can be minimized.

Therefore, similarly to the semiconductor device 51 of Embodiment 1, the semiconductor device 52 of Embodiment 2 can enhance the reliability of the device without causing electrical loss during operation of the plurality of semiconductor elements 6.

In addition, similarly to Embodiment 1, the semiconductor device 52 of Embodiment 2 can simplify the device configuration by executing the cooling operation of the double-sided cooling system described above by one cooling mechanism 9.

The plurality of semiconductor elements 6 go into a heat generation state during energization operation, and warpage is likely to occur in a warpage occurrence region of the metal base plate 1 overlapping the plurality of semiconductor elements 6 in plan view.

Meanwhile, the second main surface of the plate portion 42a of the heat dissipation member 42 overlaps most of the first main surface of each of the plurality of semiconductor elements 6 and is provided in a relatively wide area in plan view, and the plurality of column portions 42b are provided on the first main surface of the metal base plate 1. Hence, it is possible to suppress the warpage fluctuation in the warpage generation region of the metal base plate 1 mainly by the function of the column portions 42b.

As a result, the semiconductor device 52 of Embodiment 2 can further improve the reliability of the device by suppressing the occurrence of warpage of the metal base plate 1 that causes warpage of the entire device and preventing peeling at the interface between the sealing resin layer 8 and the metal base plate 1 due to warpage fluctuation of the metal base plate 1.

Note that in order to effectively suppress the warpage fluctuation in the warpage occurrence region of the metal base plate 1, it is desirable that the second main surface of the plate portion 42 a of the heat dissipation member 42 overlap ½ or more of the total area of the first main surfaces of the plurality of semiconductor elements 6 in plan view. By providing the plate portion 42a with the above structure, the area and volume of the plate portion 42a are expanded, so that the effect of suppressing the warpage fluctuation of the metal base plate 1 can be expected to be enhanced.

Note that the semiconductor device 52 of Embodiment 2 can also be applied to a structure having at least one semiconductor element 6 as in Embodiment 1.

### Embodiment 3

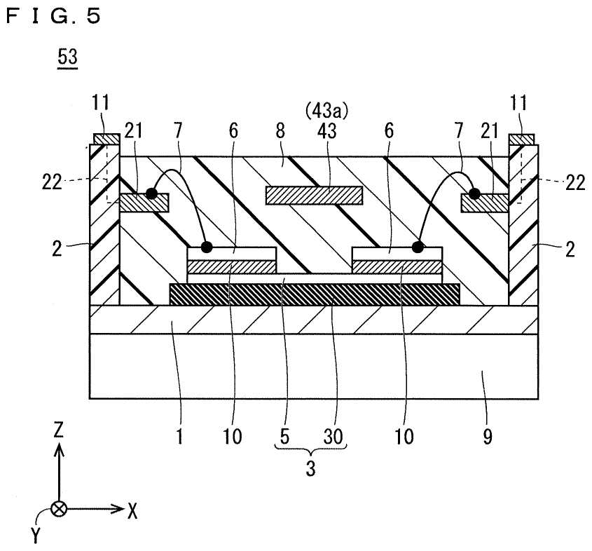

FIG. 5 is a cross-sectional view illustrating a cross-sectional structure of a semiconductor device 53 of Embodiment 3 of the present disclosure. An XYZ orthogonal coordinate system is illustrated in FIG. 5. Note that FIG. 5 corresponds to the A-A cross section of the semiconductor device 51 illustrated in FIG. 1.

Hereinafter, components similar to those of the semiconductor device 51 illustrated in FIGS. 1 to 3 will be denoted by the same reference numerals, description thereof will be omitted as appropriate, and feature portions of the semiconductor device 53 of Embodiment 3 will be mainly described.

The semiconductor device 53 of Embodiment 3 has a structure in which the heat dissipation member 4 is replaced with a heat dissipation member 43.

The heat dissipation member 43 has conductivity and includes a plurality of column portions 43b (not illustrated) and a plate portion 43a provided between the plurality of column portions 43b. The shape of the heat dissipation member 43 is substantially the same as that of the heat dissipation member 4 of Embodiment 1, the plurality of column portions 43b correspond to the plurality of column portions 4b, and the plate portion 43a corresponds to the plate portion 4a.

Therefore, similarly to the heat dissipation member 4 of Embodiment 1, the heat dissipation member 43 is provided away from a plurality of semiconductor elements 6 so that a sealing resin layer 8 between the heat dissipation member 43 and the plurality of semiconductor elements 6 does not cause dielectric breakdown during energization operation of the plurality of semiconductor elements 6. Furthermore, similarly to the heat dissipation member 4 of Embodiment 1, the heat dissipation member 43 is electrically insulated from the plurality of semiconductor elements 6.

As described above, the semiconductor device 53 uses various components such as the plurality of semiconductor elements 6, a plurality of electrical connection members 7, an insulating circuit board 3, and a metal base plate 1, which have different thermal expansion coefficients.

The plurality of electrical connection members 7 are made of a first material having conductivity, and are electrically connected to the plurality of semiconductor elements 6.

In Embodiment 3, the constituent material of the heat dissipation member 43 is adapted to the material used for the semiconductor device 53 to reduce the mismatch of the thermal expansion coefficients in the semiconductor device 53.

For example, when the first material serving as the constituent material of the electrical connection member 7 is aluminum or copper, the constituent material of the heat dissipation member 43 is also the first material of aluminum or copper. By using a material having a high thermal conductivity, such as aluminum or copper, which is the first material, as a constituent material of the heat dissipation member 43, the sealing resin layer 8 can be efficiently cooled.

As described above, the semiconductor device 53 of Embodiment 3 is characterized in that when the constituent material of the electrical connection member 7 is the first material having conductivity, the constituent material of the heat dissipation member 43 is the same first material as that of the electrical connection member 7. Examples of the first material include aluminum, copper, and the like described above.

Similarly to the heat dissipation member 4 of Embodiment 1, the heat dissipation member 43 is provided away from the plurality of semiconductor elements 6 so that the sealing resin layer 8 between the heat dissipation member 43 and the plurality of semiconductor elements 6 does not cause dielectric breakdown during energization operation of the plurality of semiconductor elements 6. Furthermore, similarly to the heat dissipation member 4 of Embodiment 1, the heat dissipation member 43 is electrically insulated from the plurality of semiconductor elements 6.

Therefore, similarly to Embodiment 1, the semiconductor device 53 of Embodiment 3 can enhance the reliability of the device without causing electrical loss during operation of the plurality of semiconductor elements 6.

In addition, similarly to Embodiment 1, the semiconductor device 53 of Embodiment 3 can simplify the device configuration by executing the cooling operation of the double-sided cooling system described above by one cooling mechanism 9.

Furthermore, in the semiconductor device 53 of Embodiment 3, since both the constituent material of the electrical connection member 7 which is an electrical connection member and the constituent material of the heat dissipation member 43 are the same first material, each of the plurality of electrical connection members 7 and the heat dissipation member 43 have the same thermal expansion coefficient.

As a result, in the semiconductor device 53 according to Embodiment 3, the difference in thermal expansion coefficient between the plurality of electrical connection members 7 and the heat dissipation member 43 in the sealing resin layer 8 can be set to “0”. Therefore, in the semiconductor device 53 of Embodiment 3, it is possible to efficiently cool the sealing resin layer 8 by enhancing the heat dissipation effect by the heat dissipation member 43 without causing the influence of the difference in thermal expansion coefficient in the sealing resin layer 8 between the plurality of electrical connection members 7 and the heat dissipation member 43.

Note that the semiconductor device 53 of Embodiment 3 can also be applied to a structure having at least one semiconductor element 6 as in Embodiment 1 and 22 Embodiment 2.

### Embodiment 4

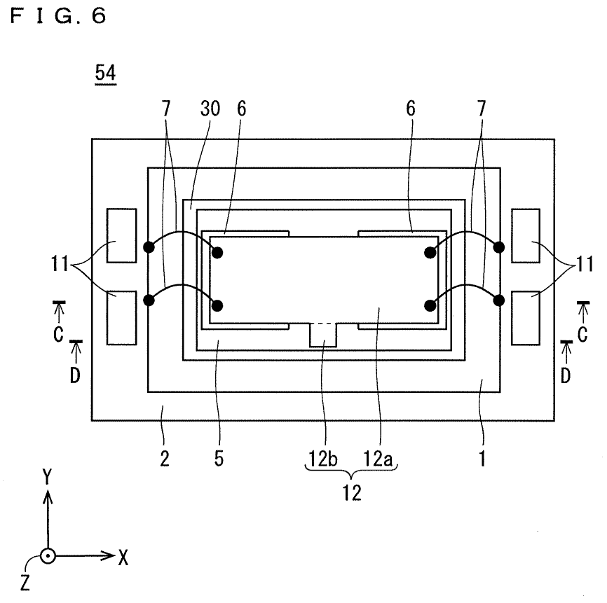

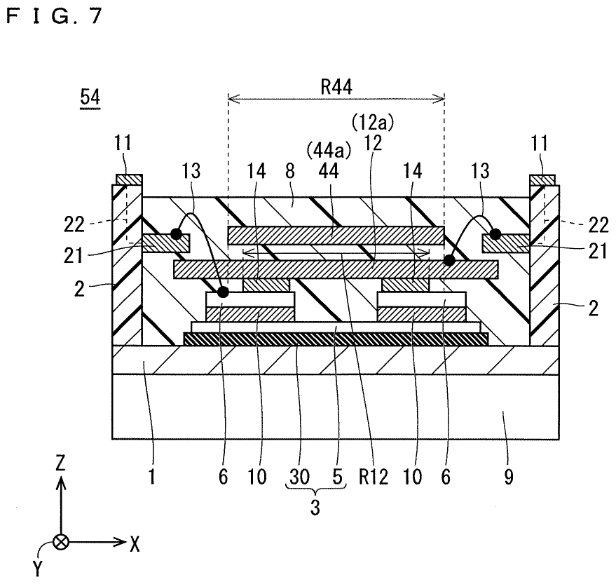

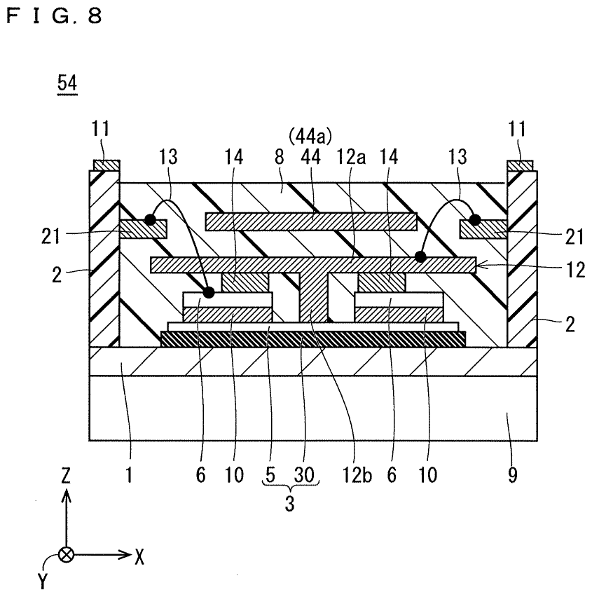

FIG. 6 is a plan view illustrating a top surface structure of semiconductor device 54 of Embodiment 4 of the present disclosure. FIG. 7 is a cross-sectional view illustrating a C-C cross-sectional structure of the semiconductor device 54 of Embodiment 4 illustrated in FIG. 6. FIG. 8 is a cross-sectional view illustrating a D-D cross-sectional structure of the semiconductor device 54 of Embodiment 4 illustrated in FIG. 6. An XYZ orthogonal coordinate system is illustrated in each of FIGS. 6 to 8. Note that in FIG. 6, a heat dissipation member 4 and a sealing resin layer 8 is omitted in order to clearly show the internal structure of the semiconductor device 54.

Hereinafter, components similar to those of the semiconductor device 51 illustrated in FIGS. 1 to 3 will be denoted by the same reference numerals, description thereof will be omitted as appropriate, and feature portions of the semiconductor device 54 of Embodiment 4 will be mainly described.

The semiconductor device 54 of Embodiment 4 newly includes a metal lead wiring member 12 and a conductive bonding material 14, and has a structure in which the heat dissipation member 4 is replaced with a heat dissipation member 44.

The heat dissipation member 44 has conductivity and includes a plurality of column portions 44b (not illustrated) and a plate portion 44a provided between the plurality of column portions 44b. The plate portion 44a of the heat dissipation member 44 has a rectangular shape in plan view, and has a relatively wide heat dissipation member forming region R44 as illustrated in FIG. 7.

As illustrated in FIGS. 7 and 8, the semiconductor device 54 of Embodiment 4 further includes the metal lead wiring member 12 and the plurality of conductive bonding materials 14 between an intermediate structure and the heat dissipation member 44. The semiconductor device 54 of Embodiment 4 includes, as an electrical connection member 7, a plurality of wires 13 serving as a linear connection member and the metal lead wiring member 12 serving as a plate-like connection member.

The plurality of conductive bonding materials 14 correspond to a plurality of semiconductor elements 6, and the second main surface of the metal lead wiring member 12 is electrically connected to the plurality of semiconductor elements 6 via the plurality of conductive bonding materials 14. That is, the metal lead wiring member 12 is bonded to the plurality of semiconductor elements 6 by the plurality of conductive bonding materials 14. As described above, the plurality of semiconductor elements 6 and the plurality of conductive bonding materials 14 correspond to each other on a one-to-one basis. Note that the conductive bonding material 14 is made of solder, soft wax, or the like.

The metal lead wiring member 12, which is a plate-like connection member, includes a plate portion 12a having a rectangular shape in plan view, and a connection portion 12b extending from a part of a side on the −Y direction side of the plate portion 12a to the −Y direction side in plan view on the XY plane as illustrated in FIG. 6. The plate portion 12a is a main portion of the metal lead wiring member 12. As described above, the metal lead wiring member 12 is a plate-like connection member whose main portion is formed in a plate shape.

As illustrated in FIG. 8, the connection portion 12b extends in the −Z direction, and the lower end of an end portion of the connection portion 12b is provided on the first main surface of a circuit pattern 5 of an insulating circuit board 3. Therefore, the metal lead wiring member 12 is electrically connected to the circuit pattern 5 via the connection portion 12b. Furthermore, the first main surface of the plate portion 12a and an intermediate connection member 21 are electrically connected via the wire 13, and the first main surface of the semiconductor element 6 and the intermediate connection member 21 are connected via the wire 13.

As described above, the metal lead wiring member 12 constitutes a main current circuit together with the plurality of wires 13, the plurality of semiconductor elements 6, and the circuit pattern 5 of the insulating circuit board 3. In particular, it is assumed that a region of the plate portion 12a where a current flows between the plurality of semiconductor elements 6 via the plurality of conductive bonding materials 14 becomes a main wiring region R12, and a relatively large current flows in the main wiring region R12.

Note that as illustrated in FIGS. 6 to 8, a region overlapping or near any of the plurality of conductive bonding materials 14 in plan view on the first main surface of the metal lead wiring member 12 is a wire bonding region. The intermediate connection member 21 is electrically connected via the wire 13 at least at one location in the wire bonding region.

As illustrated in FIG. 7, the intermediate connection member 21 is electrically connected to an external electrode 11 via an embedded connection line 22. Therefore, the wire bonding region of the metal lead wiring member 12 is electrically connected to the external electrode 11 via the wire 13, the intermediate connection member 21, and the embedded connection line 22.

Note that in FIG. 7, the external electrode 11, the intermediate connection member 21, and the embedded connection line 22 are illustrated as independent components, but a metal plate also serving as the external electrode 11, the intermediate connection member 21, and the embedded connection line 22 may be insert-molded in a resin case 2.

The electrical connection mode between the metal lead wiring member 12 and the external electrode 11 is not limited to the mode illustrated in FIGS. 6 to 8. For example, the following first to third connection modes are conceivable.

The first connection mode is a mode in which the wire bonding region of the metal lead wiring member 12 and the external electrode 11 are directly connected by a wire.

The second connection mode is a mode in which a conductive bonding material such as solder or soft wax is used instead of the wire 13, and the wire bonding region of the metal lead wiring member 12 and the intermediate connection member 21 are electrically connected by a conductive bonding member.

The third connection mode is a mode in which the plate portion 12a is extended toward the side wall of the metal lead wiring member 12 along the +X direction, and the plate portion 12 a and the embedded connection line 22 provided in the side wall of the resin case 2 are brought into contact with each other, thereby integrating the external electrode 11 and the embedded connection line 22 provided on the +X direction side with the plate portion 12a.

Hereinafter, in Embodiment 4, a structure including the insulating circuit board 3, the plurality of semiconductor elements 6, the plurality of conductive bonding materials 10, the metal lead wiring member 12, and the plurality of conductive bonding materials 14 may be referred to as an “extended intermediate structure”.

Similarly to the heat dissipation member 4 of Embodiment 1, the heat dissipation member 44 is disposed such that the second main surface of the plate portion 44a and the first main surface of the extended intermediate structure face each other. Therefore, the plate portion 44a of the heat dissipation member 44 is disposed at a position spaced apart from the first main surface of each of the metal lead wiring member 12, the insulating circuit board 3, and the plurality of semiconductor elements 6.

Similarly to the heat dissipation member 4 of Embodiment 1, the heat dissipation member 44 is provided such that the plurality of column portions 44b stand on the first main surface of the metal base plate 1. That is, the heat dissipation member 44 is provided on the first main surface of the metal base plate 1 so as to straddle the extended intermediate structure.

Then, the heat dissipation member 44 is provided away from the metal lead wiring member 12 and the plurality of semiconductor elements 6 so that the sealing resin layer 8 between the heat dissipation member 44 and the plurality of semiconductor elements 6 does not cause dielectric breakdown during energization operation of the plurality of semiconductor elements 6. Furthermore, the heat dissipation member 44 is electrically insulated from the metal lead wiring member 12 and the plurality of semiconductor elements 6.

In addition, the heat dissipation member forming region R44 of the heat dissipation member 44 is disposed to include the main wiring region R12 of the metal lead wiring member 12 in plan view. That is, the heat dissipation member forming region R44 has a shape wider than the main wiring region R12 and includes the entire main wiring region R12 in plan view.

In the structure of the semiconductor device 54 illustrated in FIGS. 6 to 8, since the bonding area between the plurality of conductive bonding materials 14 on the first main surface of the plurality of semiconductor elements 6 and the first main surface of the plate portion 12a is larger than that in the wiring structure using a linear connection member such as a wire, a large amount of heat is propagated during energization operation of the plurality of semiconductor elements 6.

In addition, since the volume of the metal lead wiring member 12, which is a plate-like connection member, is larger than the volume of a linear connection member such as the wire 13, the amount of thermal expansion is large. Therefore, the interface between an end portion of the metal lead wiring member 12 and the sealing resin layer 8 is peeled off, so that the sealing resin layer 8 is likely to be cracked with this peeled portion as a starting point.

When the crack generated in the sealing resin layer 8 develops to any one of the plurality of semiconductor elements 6, there is a problem that the semiconductor element 6 is damaged and the reliability of the device is lowered.

However, in the semiconductor device 54 of Embodiment 4, the sealing resin layer 8 is cooled by the heat dissipation path including the heat dissipation member 44 to suppress thermal expansion, thereby suppressing thermal expansion of the metal lead wiring member 12, suppressing peeling between the end portion of the metal lead wiring member 12 and the sealing resin layer 8, and maintaining high reliability of the device.

In particular, as described above, since the heat dissipation member forming region R44 of the plate portion 44a includes the main wiring region R12 of the metal lead wiring member 12 and the heat dissipation member forming region R44 is wider than the main wiring region R12, thermal expansion of the metal lead wiring member 12 can be effectively suppressed.

In such a configuration, heat from the plurality of semiconductor elements 6 and the metal lead wiring member 12 during energization operation of the plurality of semiconductor elements 6 is propagated to the entire semiconductor device 54 via the sealing resin layer 8.

In the semiconductor device 54 of Embodiment 4, most of the first main surface of each of the plurality of semiconductor elements 6 and the second main surface of the plate portion 44a face each other, and the heat dissipation member forming region R44 is set in a positional relationship including the main wiring region R12 of the metal lead wiring member 12 in plan view. Therefore, by a first cooling operation of cooling through a heat dissipation path including the heat dissipation member 44, the metal base plate 1, and the cooling mechanism 9, the heat generated from the plurality of semiconductor elements 6 and the metal lead wiring member 12 and propagated to the sealing resin layer 8 is dissipated, and the temperature rise in the region of the sealing resin layer 8 close to the plurality of semiconductor elements 6 and the metal lead wiring member 12 can be minimized.

Therefore, similarly to the semiconductor device 51 of Embodiment 1, the semiconductor device 54 of Embodiment 4 can enhance the reliability of the device without causing electrical loss during operation of the plurality of semiconductor elements 6.

In addition, similarly to Embodiment 1, the semiconductor device 54 of Embodiment 4 can simplify the device configuration by executing the cooling operation of the double-sided cooling system described above by one cooling mechanism 9.

Meanwhile, since the metal lead wiring member 12, which is a plate-like connection member, has the plate portion 12a as a main portion, a relatively large current can flow in the main wiring region R12 of the plate portion 12a during energization operation of the plurality of semiconductor elements 6. That is, the semiconductor device 54 of Embodiment 4 allows passage of a relatively large current.

However, in the semiconductor device 54 of Embodiment 4, since a relatively large current flows in the main wiring region R12, peeling is likely to occur starting from the interface between the plate portion 12a of the metal lead wiring member 12 and the sealing resin layer 8. When the peeling occurs, defects are likely to occur in the plurality of semiconductor elements 6, and some of the plurality of semiconductor elements 6 may be damaged, for example.

In the semiconductor device 54 of Embodiment 4, the plate portion 44a of the heat dissipation member 44 overlaps the plate portion 12a of the metal lead wiring member 12 in plan view, so that the metal lead wiring member 12 can be cooled by the first cooling operation of cooling through the heat dissipation path including the heat dissipation member 44 to suppress the peeling.

In particular, since the plate portion 44a of the heat dissipation member 44 of Embodiment 4 includes the main wiring region R12 in the metal lead wiring member 12 in plan view, the metal lead wiring member 12 can be more effectively cooled.

As a result, the semiconductor device 54 of Embodiment 4 can reliably avoid defects of the plurality of semiconductor elements 6 and improve reliability of the device that allows passage of a relatively large current.

In addition, since the metal lead wiring member 12 has a relatively large bonding area with the plurality of semiconductor elements 6 via the conductive bonding material 14, the semiconductor device 54 of Embodiment 4 can achieve a large current and a long life.

Furthermore, since the metal lead wiring member 12, which is a plate-like connection member, includes the main wiring region R12, a relatively large current flows in the main wiring region R12 during energization operation of the plurality of semiconductor elements 6, and the calorific value increases.

Since the plate portion 44a of the heat dissipation member 44 of Embodiment 4 is disposed to include the main wiring region R12 in the metal lead wiring member 12 in plan view, it is possible to effectively cool the main wiring region R12 by the first cooling operation of cooling through the heat dissipation path including the plate portion 44a.

As a result, the semiconductor device 54 of Embodiment 4 can reliably avoid a defect associated with heat generation in the main wiring region R12 and improve the reliability of the semiconductor device 54 that allows passage of a relatively large current.

Note that the semiconductor device 54 of Embodiment 4 can also be applied to a structure having at least one semiconductor element 6 as in the Embodiments 1 to 3.

### Embodiment 5

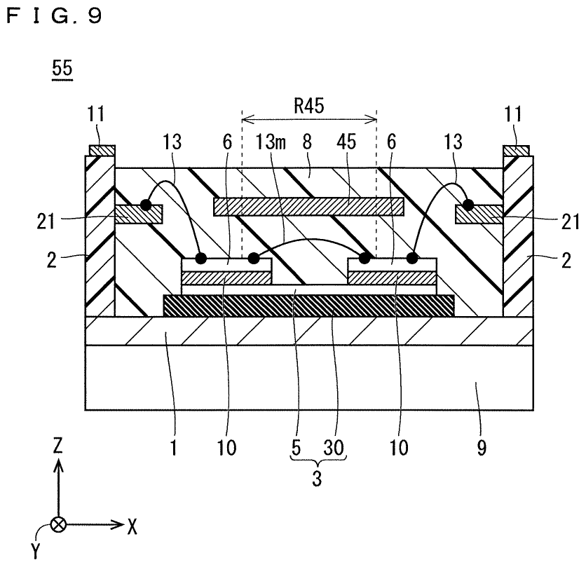

FIG. 9 is a cross-sectional view illustrating a cross-sectional structure of a semiconductor device 55 of Embodiment 5 of the present disclosure. An XYZ orthogonal coordinate system is illustrated in FIG. 9. Note that FIG. 9 corresponds to the A-A cross section of the semiconductor device 51 illustrated in FIG. 1.

Hereinafter, components similar to those of the semiconductor device 51 illustrated in FIGS. 1 to 3 will be denoted by the same reference numerals, description thereof will be omitted as appropriate, and feature portions of the semiconductor device 55 of Embodiment 5 will be mainly described.

The semiconductor device 55 of Embodiment 5 is characterized by using a plurality of wires 13, which are a plurality of linear connection members, as electrical connection members 7 for a plurality of semiconductor elements 6. Generally, a metal material having low electric resistance such as aluminum or copper is used as a constituent material of the plurality of wires 13.

The plurality of wires 13, which are a plurality of linear connection members, include a main wire 13m that electrically connects the plurality of semiconductor elements 6. The main wire 13m serves as a main current wiring member.

As described above, the plurality of wires 13 constitute a main current circuit together with the plurality of semiconductor elements 6 and a circuit pattern 5 of an insulating circuit board 3. It is assumed that a relatively large current flows in the main wire 13m functioning as a main current wiring member that allows a current to flow between the plurality of semiconductor elements 6, among the plurality of wires 13.

Both ends of each of the plurality of wires 13 including the main wire 13m are bonded to an object to be bonded by ultrasonic wire bonding processing which is ultrasonic bonding processing. In the semiconductor device 55 illustrated in FIG. 9, the object to be bonded is the first main surface of an intermediate connection member 21 or any one of the plurality of semiconductor elements 6. In this manner, both ends of the plurality of wires 13 are bonded to an object to be bonded as bonding ends by the ultrasonic bonding processing.

Therefore, the method of manufacturing the semiconductor device 55 of Embodiment 5 includes the following steps (a) and (b) as a part thereof.

Step (a) is a step of arranging an intermediate structure including the insulating circuit board 3 and the plurality of semiconductor elements 6 on the first main surface of a metal base plate 1.

Step (b) is a step of performing ultrasonic bonding processing to bond both ends of each of the plurality of wires 13 to an object to be bonded. Here, the object to be bonded includes any one of the first main surface of any of the plurality of semiconductor elements 6 or the first main surface of the plurality of intermediate connection members 21. Therefore, step (b) includes a step of performing ultrasonic bonding processing to bond one end of each of the plurality of wires 13 to any of the plurality of semiconductor elements 6.

For example, ultrasonic bonding processing is executed to bond one end of the main wire 13m onto the first main surface of one of the plurality of semiconductor elements 6, and bond the other end of the main wire 13m onto the first main surface of another of the plurality of semiconductor elements 6. In this case, both ends of the main wire 13m are bonding ends.

Step (a) described above is performed by an existing manufacturing process, step (b) described above is performed by executing ultrasonic bonding processing, and each end portion of the plurality of wires 13 subjected to the ultrasonic bonding processing in the step (b) serves as a bonding end.

Hereinafter, in Embodiment 5, a structure including the insulating circuit board 3, the plurality of semiconductor elements 6, and the plurality of wires 13 may be referred to as an “extended intermediate structure”.

Similarly to the heat dissipation member 43 of Embodiment 3, a heat dissipation member 45 is disposed such that a plate portion 45a overlaps most of the plurality of semiconductor elements 6 in plan view.

Similarly to the heat dissipation member 4 of Embodiment 1, the heat dissipation member 45 is disposed such that the second main surface of the plate portion 45a of the heat dissipation member 45 and the first main surface of the extended intermediate structure face each other. Therefore, the plate portion 45a of the heat dissipation member 45 is disposed at a position spaced apart from the first main surface of each of the insulating circuit board 3 and the plurality of semiconductor elements 6 by a distance.

Similarly to the heat dissipation member 4 of Embodiment 1, the heat dissipation member 45 is provided such that a plurality of column portions 45b stand on the first main surface of the metal base plate 1. That is, the heat dissipation member 45 is provided on the first main surface of the metal base plate 1 so as to straddle the extended intermediate structure.

The heat dissipation member 45 in the semiconductor device 55 of Embodiment 5 is provided away from the main wire 13m and the plurality of semiconductor elements 6 so that a sealing resin layer 8 between the heat dissipation member 45 and the plurality of semiconductor elements 6 does not cause dielectric breakdown during energization operation of the plurality of semiconductor elements 6. Furthermore, the heat dissipation member 45 is electrically insulated from the main wire 13m and the plurality of semiconductor elements 6.

In addition, a heat dissipation member forming region R45 at the central portion of the heat dissipation member 45 is disposed to include the main wire 13m in plan view. That is, the main wire 13m exists in the heat dissipation member forming region R45 in plan view.

In the semiconductor device 55 of Embodiment 5 illustrated in FIG. 9, a relatively large current flows through the main wire 13m that electrically connects the plurality of semiconductor elements 6 during energization operation of the plurality of semiconductor elements 6.

For this reason, when the interface between the main wire 13m and the sealing resin layer 8 is peeled off, the sealing resin layer 8 tends to be cracked starting from this peeled portion.

When the crack generated in the sealing resin layer 8 develops to any one of the plurality of semiconductor elements 6, there is a problem that the semiconductor element 6 is damaged and the reliability of the device is lowered.

In the semiconductor device 55 of Embodiment 5, the heat dissipation member forming region R45 is set so as to include the main wire 13m in plan view.

In the semiconductor device 55 having such a configuration, heat during energization operation of the plurality of semiconductor elements 6 and the main wire 13m is propagated to the entire semiconductor device 55 through the sealing resin layer 8. At this time, since the heat generated from the plurality of semiconductor elements 6 and the main wire 13m and propagated to the sealing resin layer 8 is dissipated by the first cooling operation via the heat dissipation path including the heat dissipation member 45, the metal base plate 1, and the cooling mechanism 9, the temperature rise in the region of the sealing resin layer 8 close to the plurality of semiconductor elements 6 and the main wire 13m can be minimized.

Therefore, similarly to the semiconductor device 51 of Embodiment 1, the semiconductor device 55 of Embodiment 5 can enhance the reliability of the device without causing electrical loss during operation of the plurality of semiconductor elements 6.

In addition, similarly to Embodiment 1, the semiconductor device 55 of Embodiment 5 can simplify the device configuration by executing the cooling operation of the double-sided cooling system described above by one cooling mechanism 9.

In the semiconductor device 55 of Embodiment 5, the bonding end of each of the plurality of wires 13 as the plurality of linear connection members may be in a disconnected state of being electrically disconnected from the plurality of semiconductor elements 6 due to thermal expansion of the sealing resin layer 8.

That is, when the sealing resin layer 8 thermally expands, a difference in thermal expansion coefficient between the semiconductor element 6 and the sealing resin layer 8 may apply stress to the bonding portion between the semiconductor element 6 and the plurality of wires 13 to cause disconnection of the wires 13.

The semiconductor device 55 of Embodiment 5 cools the heat accumulated in the sealing resin layer 8 by the first cooling operation through the heat dissipation path including the plate portion 45a of the heat dissipation member 45, so that it is possible to avoid a phenomenon in which any of the plurality of wires 13 is disconnected and improve the reliability of the semiconductor device.

That is, the semiconductor device 55 of Embodiment 5 cools the heat accumulated in the sealing resin layer 8 by the heat dissipation member 45 provided inside the sealing resin layer 8, and thus, it is possible to suppress expansion of the sealing resin layer 8 and prevent disconnection of the wire 13.

In addition, since the semiconductor device 55 of Embodiment 5 uses the plurality of wires 13 as electrical connection members, the degree of freedom of wiring is high. Therefore, flexible circuit design can be performed on the semiconductor device 55.

Since the plurality of wires 13 include the main wire 13m to be the main current wiring member, a relatively large current flows through the main wire 13m during energization operation of the plurality of semiconductor elements 6, and the calorific value increases.

In the semiconductor device 55 of Embodiment 5, the heat dissipation member forming region R45 in the plate portion 45a of the heat dissipation member 45 is disposed to include the main wire 13m in plan view. Therefore, the main wire 13m can be effectively cooled by the first cooling operation through the heat dissipation path including the column portion 45b.

As a result, the semiconductor device 55 of Embodiment 5 can reliably avoid a defect caused by heat generation of the main wire 13m and improve reliability of the device that allows a relatively large current to flow through the main wire 13m.

Furthermore, the semiconductor device 55 of Embodiment 5 manufactured by the method of manufacturing including the above-described steps (a) and (b) can ensure a highly stable electrical connection state with any of the plurality of semiconductor elements 6 at the bonding end of each of the plurality of wires 13 to be the plurality of linear connection members by the above-described step (b).

Note that in the structure illustrated in FIG. 9, each of the plurality of wires 13 is bonded to any one of the plurality of semiconductor elements 6 in units of a single wiring, but may be bonded to any one of the plurality of semiconductor elements 6 in units of a plurality of wirings. In addition, when bonding is performed in units of a plurality of wirings, bonding may be performed by ribbon-shaped wirings in which a plurality of wirings is arranged.

Note that the semiconductor device 55 of Embodiment 5 can also be applied to a structure having at least one semiconductor element 6 as in the Embodiments 1 to 4.

### Embodiment 6

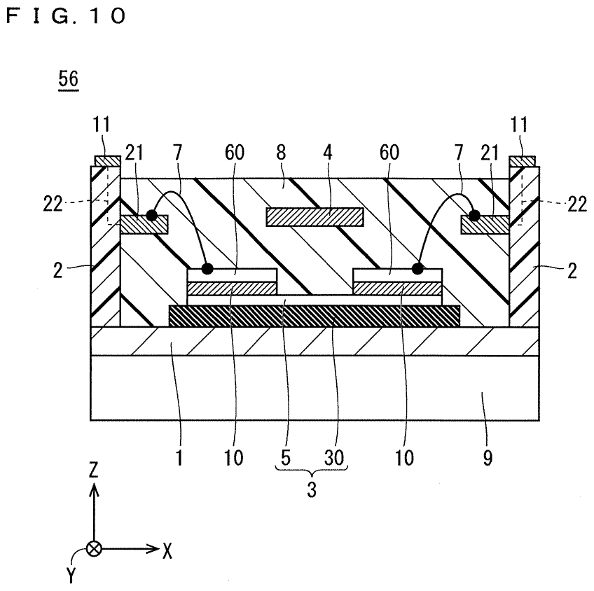

FIG. 10 is a cross-sectional view illustrating a cross-sectional structure of a semiconductor device 56 of Embodiment 6 of the present disclosure. An XYZ orthogonal coordinate system is illustrated in FIG. 10. Note that FIG. 10 corresponds to the A-A cross section of the semiconductor device 51 illustrated in FIG. 1.

Hereinafter, components similar to those of the semiconductor device 51 illustrated in FIGS. 1 to 3 will be denoted by the same reference numerals, description thereof will be omitted as appropriate, and feature portions of the semiconductor device 56 of Embodiment 6 will be mainly described.

The semiconductor device 56 of Embodiment 6 has a structure in which a plurality of semiconductor elements 6 are replaced with a plurality of SiC semiconductor elements 60.

In such a configuration, heat during energization operation of the plurality of SiC semiconductor elements 60 is propagated to the entire semiconductor device 56 via a sealing resin layer 8. Each of the plurality of SiC semiconductor elements 60 is a semiconductor element made of silicon carbide (SiC), and has a relatively large calorific value during energization operation as compared with a semiconductor element made of Si. Therefore, the increase in the operating temperature of the plurality of SiC semiconductor elements 60 is larger than the increase in the operating temperature of the plurality of semiconductor elements 6.

As in Embodiment 1, the heat dissipation member 4 is provided away from the plurality of SiC semiconductor elements 60 so that the sealing resin layer 8 between the heat dissipation member 4 and the plurality of SiC semiconductor elements 60 does not cause dielectric breakdown during energization operation of the plurality of SiC semiconductor elements 60. Furthermore, the heat dissipation member 4 is electrically insulated from the plurality of SiC semiconductor elements 60.

Therefore, similarly to Embodiment 1, the semiconductor device 56 of Embodiment 6 can enhance the reliability of the device without causing electrical loss during energization operation of the plurality of SiC semiconductor elements 60.

Since the semiconductor device 56 of Embodiment 6 includes the plurality of SiC semiconductor elements 60, the semiconductor device basically has SiC operation characteristics in which a relatively large current can flow, the semiconductor device operates at a high frequency, operates even in a high-temperature environment, has high insulation, and has a low off-voltage.

In addition, similarly to Embodiment 1, the semiconductor device 56 of Embodiment 6 can simplify the device configuration by executing the cooling operation of the double-sided cooling system described above by one cooling mechanism 9.

In the semiconductor device 56 of Embodiment 6, since the calorific value of the plurality of SiC semiconductor elements 60 during energization operation is relatively large, the operating temperature rises. For this reason, the influence of the thermal stress caused by the difference in thermal expansion coefficient between the component parts of the semiconductor device 56 increases, which causes a decrease in reliability of the device.

Meanwhile, the semiconductor device 56 of Embodiment 6 has a heat dissipation function of dissipating heat accumulated in the sealing resin layer 8 during energization operation of the plurality of SiC semiconductor elements 60 via the heat dissipation path including the heat dissipation member 4 and the metal base plate 1, and thus can suppress thermal expansion of the sealing resin layer 8.

As a result, the semiconductor device 56 of Embodiment 6 can minimize the influence of thermal stress caused by the difference in thermal expansion coefficient between the component parts of the semiconductor device 56, and improve the reliability of the device having the above-described SiC operation characteristics.

Note that in Embodiment 6 illustrated in FIG. 10, the structure in which the plurality of SiC semiconductor elements 60 are provided in the structure of Embodiment 1 illustrated in FIGS. 1 to 3 is illustrated, but it is needless to say that the structure can be modified to a structure in which the plurality of SiC semiconductor elements 60 are provided in the structures of Embodiments 2 to 5.

Furthermore, the semiconductor device 56 of Embodiment 6 can also be applied a structure having at least one SiC semiconductor element 60 as in the Embodiments 1 to 5.

Although the present disclosure has been described in detail, the above description is illustrative in all aspects, and the present disclosure is not limited thereto. It understood that many modifications not illustrated can be assumed without departing from the scope of the present disclosure.

### EXPLANATION OF REFERENCE SIGNS

1: metal base plate
2: resin case
3: insulating circuit board
4, 42 to 45: heat dissipation member
4a, 42a to 45a: plate portion
4b, 42b to 45b: column portion
5: circuit pattern
6: semiconductor element
7: electrical connection member
8: sealing resin layer
9: cooling mechanism
10, 14: conductive bonding material
11: external electrode
12: metal lead wiring member
13: wire
13m: main wire
21: intermediate connection member
22: embedded connection line
30: insulating layer
51 to 56: semiconductor device
60: SiC semiconductor element

1. A semiconductor device comprising:
a base plate having a first main surface and a second main surface;
an insulating circuit board provided on a first main surface side of the base plate and having a circuit pattern;
at least one semiconductor element provided on a first main surface side of the insulating circuit board;
a heat dissipation member having conductivity and including a plurality of column portions and a plate portion provided between the plurality of column portions, the plate portion being located on a first main surface side of the insulating circuit board and the at least one semiconductor element, the plurality of column portions being provided in a state of standing on the first main surface of the base plate; and
a resin layer provided on the first main surface of the base plate so as to cover the insulating circuit board, the at least one semiconductor element, and the heat dissipation member, wherein
the heat dissipation member is provided away from the at least one semiconductor element so that the resin layer between the heat dissipation member and the at least one semiconductor element does not cause dielectric breakdown during operation of the at least one semiconductor element, and
the heat dissipation member is electrically insulated from the at least one semiconductor element.

2. The semiconductor device according to claim 1, wherein
the plate portion of the heat dissipation member is provided so as to overlap the at least one semiconductor element in plan view.

3. The semiconductor device according to claim 1, further comprising
an electrical connection member made of a conductive first material and electrically connected to the at least one semiconductor element, wherein
the resin layer is provided to further cover the electrical connection member, and
the heat dissipation member is made of the first material.

4. The semiconductor device according to claim 1, further comprising
an electrical connection member that has conductivity and is electrically connected to the at least one semiconductor element, wherein
the electrical connection member includes a plate-like connection member whose main portion is formed in a plate shape,
the plate portion of the heat dissipation member overlaps the plate-like connection member in plan view,
the plate-like connection member is bonded to the at least one semiconductor element via a conductive bonding material, and
the heat dissipation member is provided away from the plate-like connection member so that the resin layer between the heat dissipation member and the plate-like connection member does not cause dielectric breakdown during operation of the at least one semiconductor element.

5. The semiconductor device according to claim 4, wherein
the at least one semiconductor element includes a plurality of semiconductor elements,
the plate-like connection member includes a main wiring region in which a current flows between the plurality of semiconductor elements, and
the plate portion of the heat dissipation member is disposed to include the main wiring region in plan view.

6. The semiconductor device according to claim 1, further comprising
an electrical connection member that has conductivity and is electrically connected to the at least one semiconductor element, wherein
the electrical connection member is a plurality of linear connection members, and
each of the plurality of linear connection members has a bonding end bonded to the at least one semiconductor element.

7. The semiconductor device according to claim 6, wherein
the at least one semiconductor element includes a plurality of semiconductor elements,
the plurality of linear connection members includes a main current wiring member that allows a current to flow between the plurality of semiconductor elements, and
the plate portion of the heat dissipation member is disposed to include the main current wiring member in plan view.

8. The semiconductor device according to claim 1, wherein
each of the at least one semiconductor element includes at least one SiC semiconductor element made of SiC.

9. The semiconductor device according to claim 1, wherein
the base plate includes a metal base plate, and
the semiconductor device further comprises
a cooling mechanism that is provided on a second main surface side of the metal base plate and cools the metal base plate.

10. A method of manufacturing a semiconductor device, the semiconductor device including the semiconductor device according to claim 6, the method comprising the steps of:
(a) arranging an intermediate structure including the insulating circuit board and the at least one semiconductor element on the first main surface of the base plate; and
(b) performing ultrasonic bonding processing to bond one end of each of the plurality of linear connection members to any one of the at least one semiconductor element, wherein
after execution of the step (b), the one end of each of the plurality of linear connection members is the bonding end.
